(19) United States
(12) Patent Application Publication
(10) Pub. No.: US 2024/0389485 A1
(43) Pub. Date: Nov. 21, 2024

(54) MOTT-PEROVSKITE MEMRISTOR APPLICABLE TO INTEGRATED NEUROMORPHIC DEVICE AND METHOD OF MANUFACTURING THE SAME

(71) Applicant: Industry-Academic Cooperation Foundation, YONSEI UNIVERSITY, Seoul (KR)

(72) Inventors: Hyung Ho PARK, Seoul (KR); Min Jae KIM, Yongin-si (KR); Dong Eun KIM, Gwangju (KR); Geon Woo KIM, Seoul (KR)

(21) Appl. No.: 18/640,241

(22) Filed: Apr. 19, 2024

(30) Foreign Application Priority Data
May 16, 2023 (KR) 10-2023-0062895

(51) Int. Cl. H10N 70/00; G06N 3/065; H10N 70/20

(52) U.S. Cl. CPC H10N 70/8836; H10N 30/708; H10N 70/023; H10N 70/24; G06N 3/065

(57) ABSTRACT

Provided is a Mott-piezo memristor of an ABO₃/CO composition, which has maximized piezo characteristics by using a method, such as doping, with various elements, an ABO₃ material having a perovskite structure exhibiting Mott-transition characteristics, and inserting a CO interlayer. The Mott-piezo memristor may comprise: a bottom electrode; a top electrode arranged to face the bottom electrode; and a plurality of Mott layers and a plurality of piezoelectric layers, which are arranged between the bottom electrode and the top electrode, wherein the plurality of piezoelectric layers are arranged between the plurality of Mott layers

### CROSS-REFERENCE TO RELATED APPLICATION

The present application claims priority to Korean Patent Application No. 10-2023-0062895, filed on May 16, 2023, the entire contents of which is incorporated herein for all purposes by this reference.

### BACKGROUND OF THE INVENTION

The present disclosure relates to a memristor and a method of manufacturing the same, and more specifically, to a memristor having improved piezo characteristics due to doping with a material having a perovskite structure exhibiting Mott transition characteristics and inserting an interlayer, and a method of manufacturing the same.

The memristor characteristics arise from a resistance change induced by bandfilling-control, which is a change in electronic structure due to electron-electron repulsion (e-e repulsion) of electrons within the 3d band of a transition metal in a perovskite structure-based Mott-transition material.

In addition, because perovskite-structured materials have excellent crystal contraction and expansion characteristics under pressure, examples of their application in piezo sensors have been reported.

Oxygen vacancy-based resistive memristors using Mott-transition materials may input gradual resistance values and thus may be utilized as vector-by-matrix multiplier device that enable efficient neuromorphic calculations in next-generation non-volatile resistive random-access memory (RRAM).

However, due to problems with the degradation of endurance characteristics caused by low ion mobility and clustering and ordering of oxygen vacancies, large-scale process steps have not been reached by implementing resistance change characteristics via defect control.

In addition, for existing perovskite structure-based piezo sensors, the low piezo constant of the material itself results in a high driving pressure and low touch sensitivity, and due to an insufficient pressure sensing capability at fine sensitivity, complex structural layers are bonded to the material to maximize applied pressure, creating difficulties in a manufacturing process.

In addition, there are also technical problems resulting from high integration, such as limitations in human body information processing, increased weight, and increased power consumption.

### DOCUMENTS OF RELATED ART

(Patent Document 0001) KR 10-2022-0006815A

### SUMMARY OF THE INVENTION

A technical objective to be achieved by the present disclosure is to increase ion mobility and improve characteristics of Mott memristors, such as endurance, on/off ratio, and reliability, by inducing bandfilling-control, which is a change in electronic structure due to dopant doping, and to enable their application in large-scale processes, such as cross-point array elements.

In addition, the present disclosure is proposed to solve technical problems resulting from high integration, such as limitations in human body information processing, increased weight, and increased power consumption, and to solve future technical issues in human body information processing in the field of big data.

However, a technical objective to be achieved by the present disclosure is not limited thereto, and other technical objectives that are not mentioned may be clearly understood by those skilled in the art from the following description.

To achieve the technical objective, an embodiment of the present disclosure provides a Mott-piezo memristor including: a bottom electrode; a top electrode arranged to face the bottom electrode; and a plurality of Mott layers and a plurality of piezoelectric layers, which are arranged between the bottom electrode and the top electrode, wherein the piezoelectric layers are arranged between the Mott layers.

In an embodiment of the present disclosure, each of the Mott layers may include an electron transport layer, a light-absorbing layer, and a hole transport layer, which are sequentially stacked.

In an embodiment of the present disclosure, the light-absorbing layer may have a perovskite structure.

In an embodiment of the present disclosure, the perovskite structure may be of an ABO₃ type.

In an embodiment of the present disclosure, the perovskite structure may exhibit Mott transition characteristics.

In an embodiment of the present disclosure, each of the piezoelectric layers may be selected from a binary oxide group consisting of HfO₂, ZrO₂, Ta₂O₅, or Al₂O₃.

In an embodiment of the present disclosure, piezo characteristics may be improved by doping the binary oxide material with Al, Ga, F, Si, Na, or Li.

In an embodiment of the present disclosure, each of the Mott layers may have a thickness of 10 nm to 300 nm.

In an embodiment of the present disclosure, each of the piezoelectric layers may have a thickness of 5 nm to 100 nm.

In an embodiment of the present disclosure, memristor characteristics may arise from a resistance change induced via a change in electronic structure due to electron-electron repulsion within a 3d band of a transition metal.

To achieve the technical objective, another embodiment of the present disclosure provides

a method of manufacturing a Mott-piezo memristor, the method including: preparing a memristor including a plurality of Mott layers having a perovskite structure exhibiting Mott transition characteristics; and inserting piezoelectric layers between the Mott layers.

In an embodiment of the present disclosure, each of the Mott layers may include an electron transport layer, a light-absorbing layer, and a hole transport layer, which are sequentially stacked.

In an embodiment of the present disclosure, the inserting of the piezoelectric layers may be performed via an atomic layer deposition method.

In an embodiment of the present disclosure, each of the piezoelectric layers may be selected from a binary oxide group consisting of HfO₂, ZrO₂, Ta₂O₅, or Al₂O₃.

In an embodiment of the present disclosure, piezo characteristics may be improved by doping the binary oxide material with Al, Ga, F, Si, Na, or Li.

According to an embodiment of the present disclosure, it is possible to produce a Mott-piezo memristor material of an ABO₃/CO composition, which has maximized piezo characteristics by using a method, such as doping, with various elements, an ABO₃ material having a perovskite structure exhibiting Mott-transition characteristics, and inserting a CO interlayer.

A new Mott-piezo memristor material developed in the present disclosure increases ion mobility and improves Mott memristor characteristics, such as endurance, on/off ratio, and reliability, by simultaneously implementing memristor characteristics and piezo characteristics, and may be applied in large-scale processes.

The effects of the present disclosure are not limited thereto, and it is to be understood to encompass all effects that can be inferred from the detailed description of the present disclosure or the features of the disclosure as set forth in the appended claims.

### BRIEF DESCRIPTION OF THE DRAWINGS

FIG. 1 is a structural diagram of a Mott-piezo memristor according to an embodiment of the present disclosure.

FIG. 2 is a process diagram showing the production of a reactant used in an atomic layer deposition method.

FIG. 3 is an image showing the doping ratios of dopants that may exhibit high mobility

within a LaTiO₃ material.

### DETAILED DESCRIPTION OF THE INVENTION

Hereinafter, the present disclosure is described with reference to the accompanying drawings. However, the present disclosure may be embodied in different ways and thus is not limited to embodiments described herein. In addition, portions irrelevant to the description are omitted from the drawings for clarity, and like components are denoted by like reference numerals throughout the specification.

Throughout the specification, when an element is referred to as being “connected to (accessed to, in contact with, coupled to)” another element, the element may be “directly connected to” the other element, or the element may also be “indirectly connected to” the other element with an intervening element therebetween. In addition, when an element is referred to as “including” or “comprising” another element, unless otherwise stated, the element may further include or comprise yet another element rather than preclude the yet other element.

The terms used in the present specification are only used to describe specific embodiments and are not intended to limit the present disclosure. The expression of singularity includes the expression of plurality unless clearly specified otherwise in context. In the present specification, it is to be understood that the terms such as “including,” “comprising,” or “having” are intended to indicate the existence of the features, numbers, steps, operations, components, parts, or combinations thereof disclosed in the specification, and are not intended to preclude the possibility that one or more other features, numbers, steps, operations, components, parts, or combinations thereof may exist or may be added.

Hereinafter, the embodiments of the present disclosure are described in detail with reference to the accompanying drawings.

The terms used in the present specification are defined as follows.

“LTO” refers to LaTiO₃.

“ABO₃” refers to an oxide structure of perovskite materials, such as LaTiO₃, CaTiO₃, etc.

“CO” refers to the structure of a binary oxide, such as HfO₂, ZrO₂, Ta₂O₅, or Al₂O₃.

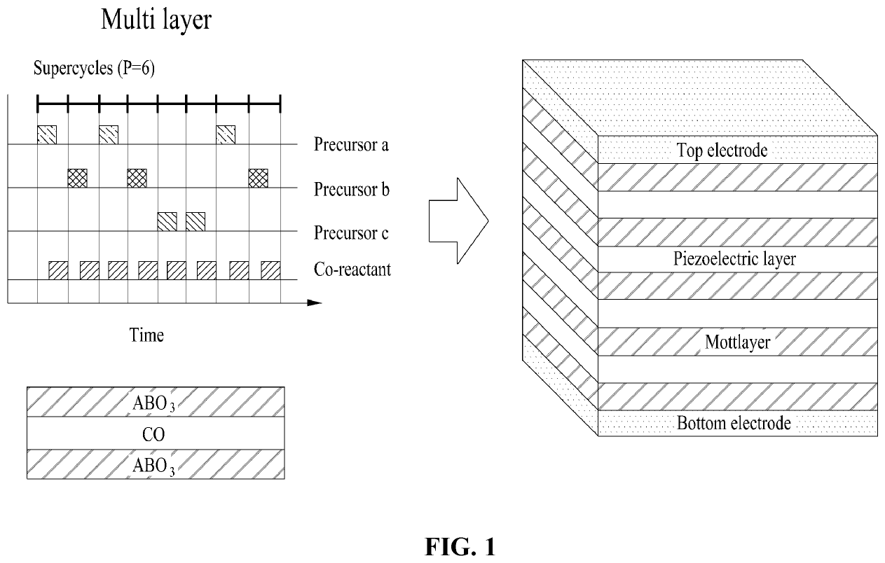

FIG. 1 is a structural diagram of a Mott-piezo memristor according to an embodiment of the present disclosure.

A Mott-piezo memristor according to an embodiment of the present disclosure is described with reference to FIG. 1.

A Mott-piezo memristor according to an embodiment of the present disclosure includes: a bottom electrode; a top electrode arranged to face the bottom electrode; and a plurality of Mott layers and a plurality of piezoelectric layers, which are arranged between the bottom electrode and the top electrode, wherein the piezoelectric layers are arranged between the Mott layers.

The bottom electrode is located on a substrate, and is preferably a conductive electrode, in particular, a transparent conductive electrode with excellent light transmission performance, but is not limited thereto.

The top electrode may include a material selected from at least one of gold, silver, platinum, palladium, copper, aluminum, carbon, cobalt sulfide, copper sulfide, nickel oxide, magnesium, calcium, and a composite thereof, but is not limited thereto.

Each of the Mott layers may include an electron transport layer, a light-absorbing layer,

and a hole transport layer, which are sequentially stacked. The light-absorbing layer acts as a photoelectric conversion layer that separates electrons and holes from each other to generate current, wherein the electrons are transferred to the electron transport layer, and the holes are transferred to the hole transport layer.

The light-absorbing layer may have a perovskite structure, and the perovskite structure may be of the ABO₃ type. In this regard, the perovskite structure may exhibit Mott transition characteristics. The Mott transition characteristics are a transition phenomenon that occurs between a metallic state and a non-metallic state, and this phenomenon occurs when the potential energy rapidly decreases near the equilibrium position due to a shielding effect, thereby preventing electrons bound to one atom from moving to the state of another atom. Mott-transition materials are materials of which the electrical conductivity transitions from an insulator to a conductor at a specific temperature, and when such materials are heated by passing current, it is possible to observe a vibration phenomenon in which an insulator state and a conductor state change periodically.

Each of the piezoelectric layers may be selected from a binary oxide group consisting of HfO₂, ZrO₂, Ta₂O₅, or Al₂O₃. It is possible to develop a Mott-piezo memristor material having an ABO₃/CO structure by introducing a binary oxide (HfO₂, ZrO₂, Ta₂O₅, or Al₂O₃) exhibiting high piezoelectric characteristics into an interlayer.

Piezo characteristics may be improved by doping the binary oxide material with Al, Ga, F, Si, Na, or Li. It is possible to locally enhance piezo potential and maximize piezo characteristics via a method of bandwidth control by doping the existing binary oxide with an element, such as Al, Ga, F, Si, Na, or Li, as a dopant exhibiting high mobility within a perovskite-structured material. However, the present disclosure is not limited to these elements.

Each of the Mott layers may have a thickness of 10 nm to 300 nm.

Each of the piezoelectric layers may have a thickness of 5 nm to 100 nm.

The memristor characteristics may arise from a resistance change induced via a change in electronic structure due to electron-electron repulsion within a 3d band of a transition metal. By inducing bandfilling-control via dopant doping, ion mobility is increased, and the memristor characteristics such as endurance, on/off ratio, and reliability are exhibited.

Hereinafter, a method of manufacturing a Mott-piezo memristor according to another embodiment of the present disclosure is described.

A method of manufacturing a Mott-piezo memristor, according to an embodiment of the present disclosure, may include: preparing a memristor including a plurality of Mott layers having a perovskite structure exhibiting Mott transition characteristics; and inserting piezoelectric layers between the Mott layers.

The first step is the preparing of the memristor including the plurality of Mott layers having the perovskite structure exhibiting the Mott transition characteristics. In the memristor including the plurality of Mott layers, a top electrode, and a bottom electrode, each of the Mott layers may include an electron transport layer, a light-absorbing layer, and a hole transport layer, which are sequentially stacked. The light-absorbing layer acts as a photoelectric conversion layer that separates electrons and holes from each other to generate current, wherein the electrons are transferred to the electron transport layer, and the holes are transferred to the hole transport layer.

The inserting of the piezoelectric layers may be performed via an atomic layer deposition method.

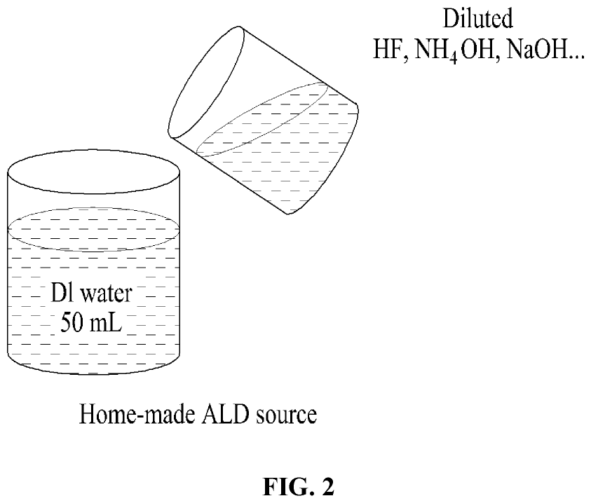

FIG. 2 is a process diagram showing the production of a reactant used in an atomic layer deposition method.

The atomic layer deposition method allows for optimization of a composition and thickness of the core material and interlayer via control in atomic units by controlling various deposition conditions, such as a supercycle, deposition temperature, and pulse/purge time, and thus enables easy formation of a Mott-piezo memristor having an ABO₃/CO structure.

In an embodiment of the present disclosure, the deposition method is preferably performed at a pressure of 1×10⁻² torr to 1×10⁻⁴ torr and at a temperature of 200° C. to 350° C. Each of the deposited Mott layers may have a thickness of 10 nm to 300 nm, and each of the piezoelectric layers may have a thickness of 5 nm to 100 nm.

Each of the piezoelectric layers may be selected from a binary oxide group consisting of HfO₂, ZrO₂, Ta₂O₅, or Al₂O₃. It is possible to develop a Mott-piezo memristor material having an ABO₃/CO structure by introducing a binary oxide (HfO₂, ZrO₂, Ta₂O₅, or Al₂O₃) exhibiting high piezoelectric characteristics into an interlayer.

Piezo characteristics may be improved by doping the binary oxide material with Al, Ga, F, Si, Na, or Li. It is possible to locally enhance piezo potential and maximize piezo characteristics via a method of bandwidth control by doping the existing binary oxide with an element, such as Al, Ga, F, Si, Na, or Li, as a dopant exhibiting high mobility within a perovskite-structured material. However, the present disclosure is not limited to these elements.

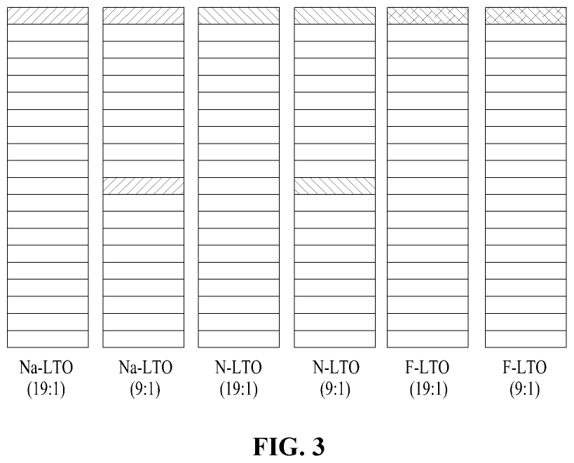

FIG. 3 is an image showing the doping ratios of dopants that may exhibit high mobility within a LaTiO₃ material.

Referring to FIG. 3, deposition conditions in which a Mott bandfilling phenomenon occurs may be implemented by controlling the type, amount and combination of dopants (Na, Li, F) that may exhibit high mobility within a LaTiO₃ material.

The description of the present disclosure provided above is for illustrative purposes, and those skilled in the art will understand that the present disclosure can be easily modified into other specific forms without changing the inventive concept or essential features of the present disclosure. Therefore, it should be understood that the foregoing embodiments are provided for illustrative purposes only and are not to be construed in any way as limiting the present disclosure. For example, each component described as a single type may be implemented in a distributed manner, and likewise, components described as being distributed may be implemented as a combined type.

The scope of the present disclosure should be defined by the appended claims, and any changes or modifications derived from the appended claims and equivalents thereof should be construed as falling within the scope of the present disclosure.

What is claimed is:

1. A Mott-piezo memristor comprising:
a bottom electrode;
a top electrode arranged to face the bottom electrode; and
a plurality of Mott layers and a plurality of piezoelectric layers, which are arranged between the bottom electrode and the top electrode,
wherein the plurality of piezoelectric layers are arranged between the plurality of Mott layers.

2. The Mott-piezo memristor of claim 1, wherein each of the plurality of Mott layers comprises an electron transport layer, a light-absorbing layer, and a hole transport layer, which are sequentially stacked.

3. The Mott-piezo memristor of claim 2, wherein the light-absorbing layer has a perovskite structure.

4. The Mott-piezo memristor of claim 3, wherein the perovskite structure is of an ABO₃ type.

5. The Mott-piezo memristor of claim 3, wherein the perovskite structure exhibits Mott transition characteristics.

6. The Mott-piezo memristor of claim 1, wherein each of the plurality of piezoelectric layers comprises a binary oxide material which is selected from a binary oxide group consisting of HfO₂, ZrO₂, Ta₂O₅, or Al₂O₃.

7. The Mott-piezo memristor of claim 6, wherein piezo characteristics are improved by doping the binary oxide material with Al, Ga, F, Si, Na, or Li.

8. The Mott-piezo memristor of claim 1, wherein each of the plurality of Mott layers has a thickness of 10 nm to 500 nm.

9. The Mott-piezo memristor of claim 1, wherein each of the plurality of piezoelectric layers has a thickness of 5 nm to 200 nm.

10. The Mott-piezo memristor of claim 1, wherein memristor characteristics arise from a resistance change induced via a change in electronic structure due to electron-electron repulsion within a 3d band of a transition metal.

11. A method of manufacturing a Mott-piezo memristor, the method comprising:
preparing a memristor comprising a plurality of Mott layers each having a perovskite structure exhibiting Mott transition characteristics; and
inserting a plurality of piezoelectric layers between the plurality of Mott layers.

12. The method of claim 11, wherein each of the plurality of Mott layers comprises an electron transport layer, a light-absorbing layer, and a hole transport layer, which are sequentially stacked.

13. The method of claim 11, wherein the inserting of the plurality of piezoelectric layers is performed via an atomic layer deposition method.

14. The method of claim 13, wherein the atomic layer deposition method is performed at a process pressure of 1×10⁻¹ torr to 1×10⁻⁴ torr and at a process temperature of 200° C. to 400° C.

15. The method of claim 11, wherein each of the plurality of piezoelectric layers comprises a binary oxide material which is selected from a binary oxide group consisting of HfO₂, ZrO₂, Ta₂O₅, or Al₂O₃.

16. The method of claim 15, wherein piezo characteristics are improved by doping the binary oxide material with Al, Ga, F, Si, Na, or Li.
